(19) United States
(12) Patent Application Publication
(10) Pub. No.: US 2010/0279436 A1
(43) Pub. Date: Nov. 4, 2010

(54) Inspection Method For Integrated Circuit Manufacturing Processes

(75) Inventors: Hsueh-Hung Fu, Hsin-Chu (TW); Tsung-Fu Hsieh, Hsinchu City (TW); Chih-Wei Chang, Hsin Chu (TW); Shih-Chang Chen, Hsin-Chu (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/433,525

(22) Filed: Apr. 30, 2009

(51) Int. Cl. H01L 21/66

(52) U.S. Cl. 438/14; 257/E21.521

(57) ABSTRACT

The present disclosure provides a method for manufacturing integrated circuit devices including an electron beam inspection. The method includes forming a silicide region on a substrate. In an embodiment, the silicide region is formed to provide contact to a device feature such as a source or drain region. An electron beam scan is then performed on the substrate. The electron beam scan includes a first scan and a second scan. The first scan includes a lower landing energy than the second scan. In an embodiment, the first scan provides a dark silicide image analysis and a bright image analysis. In an embodiment, the second scan provides a dark silicide image analysis. The method continues to form a conductive plug after performing the electron beam scan.

### BACKGROUND

The present disclosure relates generally to integrated circuit manufacturing processes and in particular to an in-line inspection method for determining a defect during the integrated circuit manufacturing process.

Charged particle beam systems such as an electron beam (e-beam) inspection system may be used in integrated circuit manufacturing processes. The systems have high resolution that are capable of identifying small physical defects, including defects not located by optical inspection systems typically used during the manufacturing processes. Furthermore, e-beam inspection may be implemented in-line without requiring physical destruction of the sample.

A typical process performed during the integrated circuit manufacturing process is the forming of conductive, silicide regions. For example, silicide regions may be used as contacts to transistor elements such as source, drain, and/or gate elements. With decreasing technology nodes (e.g., line widths), silicidation has become more challenging. Identification of defects in the silicided areas (e.g., missing silicide, improper diffusion of silicide) is more critical as it can affect device properties including causing higher leakage, opens, shorts, and other possible defects. Therefore, what are needed are mechanisms to improve the above deficiencies.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flow chart illustrating an embodiment of a method of integrated circuit manufacturing including an e-beam inspection after forming a tungsten plug.

FIG. 2 is a flow chart illustrating an embodiment of a method of integrated circuit manufacturing including an e-beam inspection after forming a silicide region.

FIG. 3 is a flow chart illustrating an embodiment of a method of post-silicide electron beam analysis that may be used in the method of FIG. 2.

FIGS. 4 and 5 illustrate sectional views of embodiments of devices analyzed by the method of FIG. 3.

FIG. 6 illustrates a diagram of an embodiment of a wafer map generated by the method of FIG. 3.

FIGS. 7, 8, and 9 illustrate graphs of embodiments of monitoring a leakage trend of a plurality of wafers.

### SUMMARY

Provided in an embodiment is a method of integrated circuit manufacturing. The method includes forming a silicide region on a semiconductor substrate. An electron beam (e-beam) scan of the semiconductor substrate is performed. The e-beam scan includes a first scan and a second scan. In an embodiment, the first scan has a lower landing energy than the second scan. A conductive plug is formed coupled to the silicide region after performing the electron beam scan.

In another embodiment, a method of integrated circuit manufacturing is provided the method includes forming a silicide region on a semiconductor substrate. A first electron beam scan of the semiconductor substrate is performed. The first e-beam scan provides both a bright silicide image (BSI) and a dark silicide image (DSI). A second electron beam scan of the semiconductor substrate is then performed. The second electron beam scan provides a second (e.g., enhanced) dark silicide image (DSI).

In a further embodiment a method of integrated circuit manufacturing is provided. A first electron beam scan of a semiconductor substrate is performed. The first electron beam scan is at a first landing energy. A second electron beam scan is then performed on the semiconductor substrate. The second electron beam scan is at a second landing energy. The second landing energy is higher than the first landing energy. Further, either the first and the second electron beam scan may be modified as a scanning method (Enforced patch image collection and analysis: EPICA) on the semiconductor substrate to monitor a background gray level value (GLV).

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. The inspection of the silicide is one process that may benefit from the introduction of charged particle beam inspection systems (e-beam) inspection as described herein. However, one of ordinary skill in the art may recognize other manufacturing processes that may similarly benefit including, for example, formation of another conductive region in addition to or in lieu of a silicide region (feature).

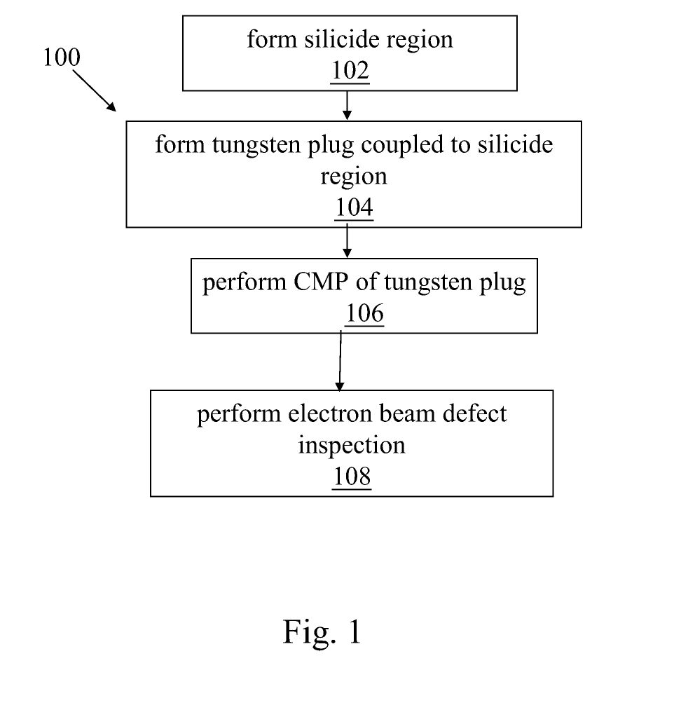

FIG. 1 is a flowchart illustrating an embodiment of a method 100 for defect inspection in an integrated circuit manufacturing process. The method 100 begins at step 102 where a silicide region is formed. The silicide region forms a contact or portion thereof, for example, providing electrical and/or physical coupling to a doped region of the substrate (e.g., a source/drain region of a transistor). The method then proceeds to step 104 where a plug is formed coupled to the silicide region. Typically the plug is a tungsten plug. The plug may be formed by etching a via (e.g., contact hole) in a layer (e.g., dielectric) overlying the formed silicide region and filling the via with conductive material, typically tungsten. The plug is also known in the art as a contact. The method 100 then proceeds to step 106 where a chemical mechanical polish (CMP) process is performed to complete the formation of the conductive plug. The CMP process typically provides a planar top surface of the plug which may be coupled to a conductive line or interconnect. Formation of a conductive plug is known in the art, for example, as described in U.S. Pat. No. 7,224,068 to Tseng et al., which is hereby incorporated by reference in its entirety.

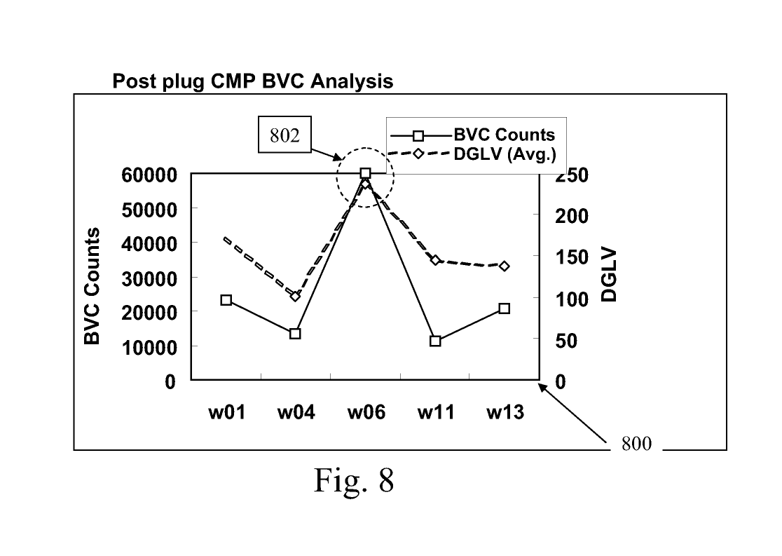

The method 100 then proceeds to step 108 where an electron beam (e-beam) defect inspection process is performed. It is noted that in the method 100 the e-beam inspection process occurs after the formation of the tungsten plug -- after the CMP processing of the tungsten plug. The e-beam inspection of step 108 may include a bright voltage contrast (BVC) and/or a dark voltage contrast (DVC) defect inspection. BVC defect inspection may locate leakage-inducing defects. DVC defect inspection may include identification of an open in the integrated circuit (e.g., an open caused by a defect in forming the conductive plug). The BVC and/or DVC inspections may include identification of gray level value (GLV). One or more GLVs may be classified to predict various defects. The GLV (or gray scale image) may be correlated to a leakage level for the device. See the discussion below with reference to FIG. 8. The e-beam inspection of step 108 occurs at a single scan condition of the e-beam; that is, a single landing energy is used.

Embodiments of the method 100 may provide several disadvantages. For example, the e-beam defect inspection (step 108) occurs after the formation of the tungsten plug. In a typical manufacturing process this occurs several days (e.g., 10 or more days) after the silicide process. Therefore, any defect attributed to the silicide may be uncorrected for some period of time. Furthermore, the one scanning condition reduces the defects that may be identified and/or classified by analysis of the inspection results. The method 100 also provides an image analysis that may identify an erroneous trend due to the background gray level identified by the scan. For example, the background gray level may reach saturation which can cause erroneous readings or the image may include noise (e.g., nuisance) that may lead to improper analysis.

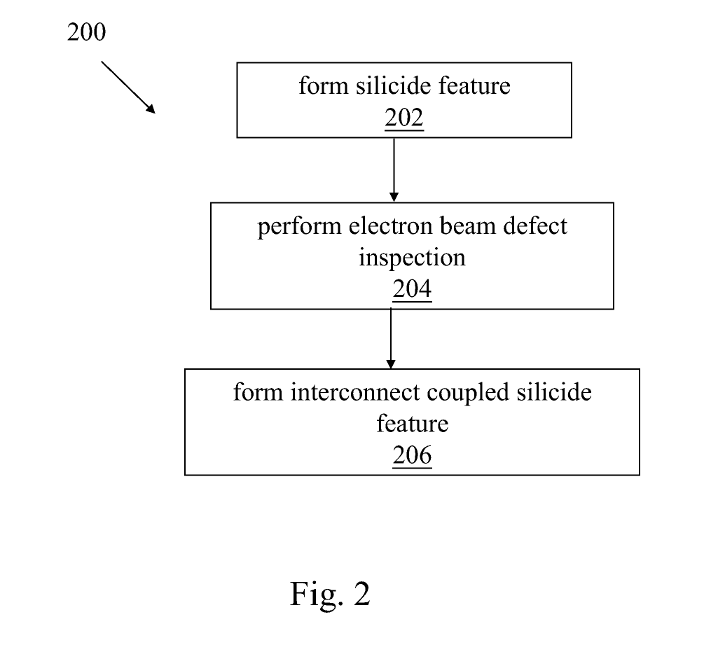

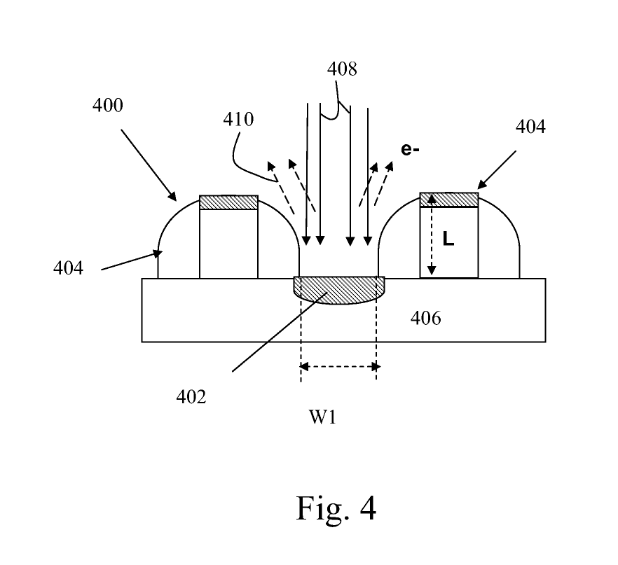

Referring now to FIG. 2, a method 200 for defect inspection in an integrated circuit manufacturing process is illustrated. The method 200 begins at step 202 where a silicide feature is formed on a semiconductor substrate. The silicide feature may be coupled to an active element of an integrated circuit device, for example, a source or drain of a transistor. The silicide feature may reduce the resistance of an interconnect that will be coupled to the active element (e.g., a conductive plug or via) such as, in step 206. An exemplary silicide feature is illustrated in FIG. 4, element 402. The silicide feature may include a silicide such as nickel silicide, cobalt silicide, tungsten silicide, tantalum silicide, titanium silicide, platinum silicide, erbium silicide, palladium silicide, and/or combinations thereof. In an embodiment, the silicide feature is formed by depositing a metal layer including a metal that can form a silicide such as nickel, cobalt, tantalum, titanium, platinum, erbium, palladium, and/or tungsten. The metal may be deposited using conventional processes such as physical vapor deposition (PVD) (sputtering), chemical vapor deposition (CVD), plasma-enhanced chemical vapor deposition (PECVD), atmospheric pressure chemical vapor deposition (APCVD), low-pressure CVD (LPCVD), high density plasma CVD (HDPCVD), or atomic layer CVD (ALCVD). The metal is then annealed to form silicide. The annealing may use a rapid thermal anneal (RTA) in a gas atmosphere such as Ar, He, N₂, or other inert gas. A second annealing may be required to make a stable silicide. The un-reacted metal is then removed. In an embodiment, the silicide is formed by a self-aligned silicide process (salicide process).

The method 200 then proceeds to step 204 where an in-line (e.g, during manufacturing processing) inspection is performed using a charged particle beam system. The charged particle beam system is referred to herein as an electron beam (e-beam) system; however, other embodiments may be possible. An example of an e-beam system is a scanning electron microscope (SEM). The use of an SEM tool to perform inspection of integrated circuit devices is described in U.S. Pat. No. 6,645,781 to Jiang et al, which is hereby incorporated by reference in its entirety. E-beam inspection systems also include tools manufactured by Hermes-Microvision, Inc. including those marketed as “E-scan.”™

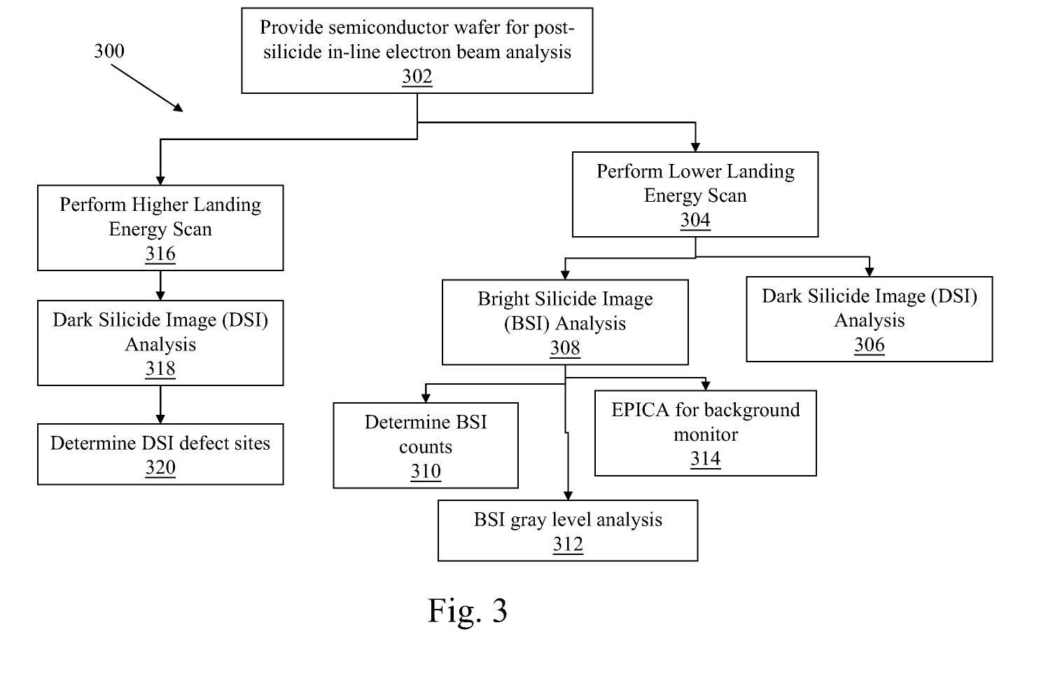

Step 204 including electron beam defect inspection is described in further detail with reference to FIG. 3. However, it noted generally the e-beam inspection 204 occurs following the formation of the silicide feature and prior to the formation of a subsequent feature providing contact to the silicide feature (e.g., the tungsten plug described above with reference to steps 104 and 106 of the method 100). The e-beam inspection 204 may include scanning a semiconductor substrate or portion thereof. The e-beam inspection 204 may scan active devices (e.g., transistors, memory elements) as well test structures. As described in further detail below, the e-beam inspection 204 includes a plurality of scanning conditions to identify different defects and/or parameters associated with the scanned device(s). Example device parameters that are identified (e.g., predicted) include leakage (e.g., junction leakage), sheet resistance (Rs), contact resistance (Rc), and/or other parameters. Example physical properties (e.g., defects) that may be identified include substrate dislocations, poor silicide formation (e.g., too narrow of a silicide feature, silicide is not formed), silicide diffusion (e.g., diffusion under adjacent spacer elements associated with a transistor gate), and/or other defects. The electron beam defect inspection 204 may be performed on multiple wafers per lot, every wafer, and/or on any other sampling plan determined by the requirements of the manufacturing processes.

The method 200 then proceeds to step 206 where an interconnect is formed coupled to the silicide feature. The interconnect may be a conductive plug providing contact to the underlying device feature and the silicide feature. An example conductive plug is a tungsten plug, however, other materials are possible. An exemplary plug is described above with reference to step 104 and 106 of the method 100.

Referring now to FIG. 3, illustrated is an embodiment of a method 300 of post-silicide in-line electron beam analysis method. The method 300 may be substantially similar to step 204, described above with reference to FIG. 2. The method 300 may be performed following the formation of a silicide region and prior to the formation of a contact (e.g., plug or interconnect) coupled to the silicide region. FIGS. 4, 5, 6, 7, 8, and 9 include exemplary embodiments of one or more steps of the method 300.

The method 300 begins at step 302 where a semiconductor wafer is provided for electron beam (e-beam) inspection. The semiconductor wafer may be partially processed through an integrated circuit manufacturing process and include one or more active devices (e.g., transistors, memory components (SRAM)) partially or completely formed thereon. The semiconductor wafer includes at least one silicide region formed thereon. The silicide region may be substantially similar to the silicide feature described above with reference to step 202 of the method 200.

The method 300 then continues to step 304 where a lower landing energy scan is performed. The method 300 may also continue to step 316 where a higher landing energy scan is performed. The scans of steps 304 and 316 may be performed serially and in any sequence, or concurrently. Though described herein as an e-beam scan, the scans may be performed by any charged particle beam system. The e-beam scan may be performed by equipment substantially similar to as described above with reference to step 204 of the method 200. The higher landing energy scan 316 may be performed using a landing energy of approximately 500 to 700 eV, by way of example only and not intended to be limiting. The lower landing energy scan 304 may be performed using a landing energy of approximately 300 eV, by way of example only and not intended to be limiting.

The higher landing energy scan 316 and/or the lower landing energy scan 304 may include one or more techniques that may increase the efficiency and/or effectiveness of the scan. In an embodiment, the scan 304 and/or 316 includes a scanning condition that provides an appropriate landing energy and a threshold tuning component. The threshold tuning component of the scanning condition provides to enhance the contrast between an image representing a defect and the surrounding area. In an embodiment, the scan 304 and/or 316 include an image noise filtering component. The image noise filtering component may provide to remove images (e.g., spots) provided by the scan that do not illustrate true defects. The images produced that do not illustrate true defects and/or improperly represent true defects are termed noise. For example, a blurred shadow effect (noise) may occur around a defect that may provide for improper analysis of the data gathered from the scan. The noise filtering may be performed by providing an upper and lower reference scan that are used to identify and remove the noise.

The scan 304 and/or 316 may also include gathering of gray level value images. The GLV may include an assessment of defect GLV (DGLV) and/or a reference GLV (RGLV). The GLV may be correlated to one or more device defects and/or parameter levels (e.g., leakage levels). The assessment of GLV may require a logic analysis.

Referring again to FIG. 3, the higher landing energy scan 316 is now described in further detail. The higher landing energy scan 316 provides for a Dark Silicide Image (DSI) analysis (or methodology), illustrated as step 318. Specifically, step 318 may be an enhanced DSI analysis, for example in comparison to the DSI analysis of the lower landing energy can (step 306 described below). The DSI methodology 318 may include analysis of an n-type field effect transistor (NFET) and/or a p-type field effect transistor (PFET). The DSI analysis 318 allows the e-beam scan to detect defects such as a residue and/or poor silicide formation. These defect sites may provide for high sheet resistance (Rs) and/or high contact resistance (Rc). The DSI analysis 318 identifies these defects as they induce a dark silicide image in the higher landing energy scan 316.

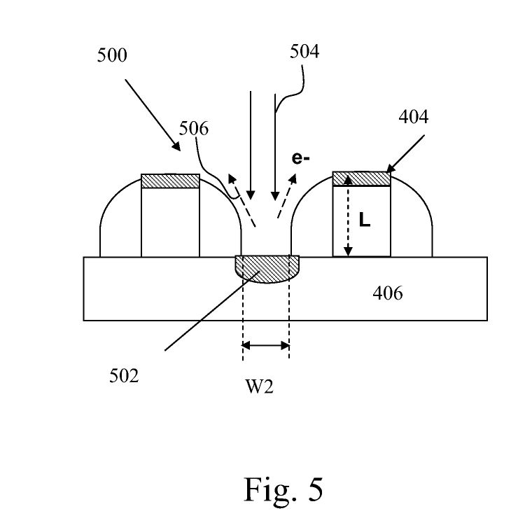

FIGS. 4 and 5 provide exemplary devices and their analysis using the DSI methodology. FIG. 4 illustrates a device 400 including a plurality of gate elements 404 (including, for example, a gate dielectric, gate electrode, silicide contact region, spacer elements) and an active area (OD) opening of width W1 formed on a semiconductor substrate 406. The aspect ratio of the device 400 is defined as L (e.g., gate height) over W1. A silicide region 402 is located between the gate elements 404. The silicide region 402 may be substantially similar to the silicide region described above with reference to step 202 of FIG. 2. An e-beam tool provides electron (e-) beams 408 which are incident on the silicide region 402. The beams 408 are reflected from the silicide region 402, depicted as reflected beams 410.

FIG. 5 illustrates a device 500 that is substantially similar to the device 400 except that the active area is decreased in width, illustrated as W2. The aspect ratio of the device 500 is defined as L (e.g., gate height) over W2. Thus, the aspect ratio of device 500 is greater than that of device 400. A silicide region 502 is substantially similar to the silicide region 402, but smaller in size. An e-beam tool provides electron (e-) beams 504 which are incident on the silicide region 504. The beams 504 are reflected from the silicide region 502, depicted as reflected beams 506. It is noted that due to the decreased width W2, the beams 504 that are incident on the silicide area are fewer in comparison to the device 400. Therefore, the reflected beams 506 are also fewer in comparison to the device 400. Thus, the device 500 provides a darker site than that of the device 400 in a DSI analysis.

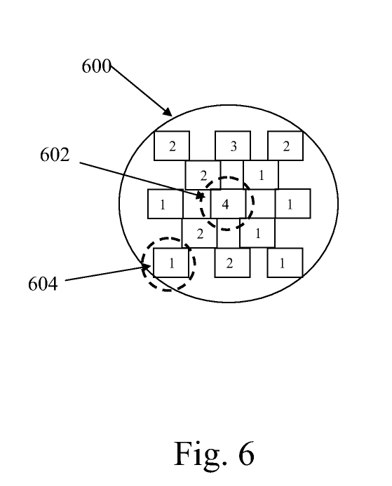

The DSI analysis 318 may include forming a wafer map illustrating the DSI density at one or more locations across a semiconductor wafer scanned during the higher landing energy scan 316. An exemplary DSI density map 600 is illustrated in FIG. 6. The DSI density map 600 indicates relative brightness of the scanned area (e.g., a scale representing relative densities is illustrated as reference numbers 1-4, this scale is provided for ease of description only and any distinguishing feature may be possible (e.g., color)). For example, the DSI density map 600 may indicate higher DSI density areas 602 and lower DSI density areas 604. The DSI density map 600 may be used to develop, generate, predict, and/or otherwise provide correlation to a wafer map that illustrates a parameter's value, such as sheet resistance (Rs), across the wafer. For example, a higher density DSI area may indicate a higher Rs area. An Rs value (or range of values) may correlate to a density (or range of densities) provided by the DSI analysis (e.g., illustrated on the DSI map).

The method 300 then proceeds to use the DSI analysis 318 to locate defects on the semiconductor wafer in step 320. The semiconductor wafer may then be dispositioned accordingly, for example, reworked, scrapped, potential yield loss calculated, corrective action performed, and/or other dispositions. The defects located by the DSI analysis include poor silicide feature formation.

In an embodiment, the defects identified in step 320 may be confirmed by performing a transmission electron microscopy (TEM) on the area in which a defect has been located by the DSI. The TEM may illustrate for, example poor silicide formation and/or lack of silicide formation. The defective silicide formation may be attributed to a narrow active area (OD) opening between gate structures, as described above.

Referring again to FIG. 3, the lower landing energy scan 304 is now described in further detail. The lower landing energy scan 304 includes a scan at a lower energy level than that of the scan 316. The lower landing energy scan 304 may include an enforced patch image collection scan. The enforced patch image collection provides for scanning images across the wafer, compiling them, and using them in the analysis to monitor and account for the background grey levels. The enforced patch collection, and analysis, is described herein as EPICA.

The lower landing energy scan 304 provides for a Bright Silicide Image (BSI) analysis, illustrated as step 308 and may also provide for a Dark Silicide Image (DSI) Analysis, illustrated as step 310. The DSI Analysis of step 306 may be substantially similar to the DSI analysis 318 described above, except however, it may be provided using a lower energy scan. (Thus, step 306 may be described as enhanced DSI, however the methodology, defects identified (e.g., FIGS. 4 and 5), and the like may be substantially similar.) In an embodiment, the scan includes a monitor of junction leakage.

The BSI analysis includes three parts: a determination of the BSI counts 310, a BSI gray level analysis 312, and an EPICA monitor 314. The determination of the BSI counts 310 includes a numerical representation of the number of images (e.g., “bright” spots) detected by the BSI analysis 308. The BSI counts 310 may be determined from an active device (e.g., an SRAM) and/or from a test structure. For example, it is possible to provide a test structure that indicates the same trend of BSI counts as an active device (e.g., SRAM).

The BSI gray level analysis 312 allows for determining a trend, a relative value, and/or an absolute value (or range thereof) for a device parameter. For example the BSI gray level analysis 312 may allow for a leakage level estimation of the associated wafer, or portion thereof. The BSI gray level analysis 312 may provide for a brightness density wafer map, similar to the density map 600, described above with reference to FIG. 6. The BSI gray level analysis 312 may also be used to identify trends from wafer to wafer or lot to lot.

The EPICA monitor 314 allows for the dark pixels to be removed from the BSI analysis 308. Removing the dark pixels allows for better comparison of the gray level analysis 312 and/or the BSI counts 310. Thus, the EPICA monitor 314 may provide for a better comparison of leakage values between portions of the semiconductor wafer. Any number of regions may be sampled for the EPICA monitor 314. Any location and/or configuration of regions may be sampled for the EPICA monitor 314. Embodiments of the EPICA monitor described herein may be advantageous when used in the electron beam defect inspection at various other points in the manufacturing process including, for example, after CMP processing of a plug overlying the silicide region (e.g., step 108 of the method 100, illustrated above in FIG. 1). For example, the EPICA monitor may improve the efficiency and/or effectiveness of a BVC or DVC analysis.

In an embodiment, the BSI analysis 308 allows for defect classification and/or leakage analysis. The BSI analysis 308 may be verified by wafer assessment testing (WAT) and/or TEM analysis. In an embodiment, the BSI analysis 308 may identify defect locations (a leakage site) which is confirmed (e.g., by TEM) to have a substrate dislocation. Other defects identified may include silicide diffusion.

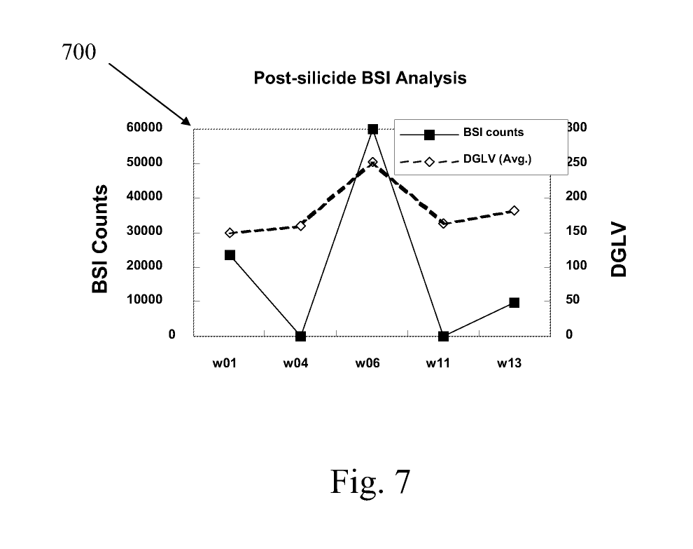

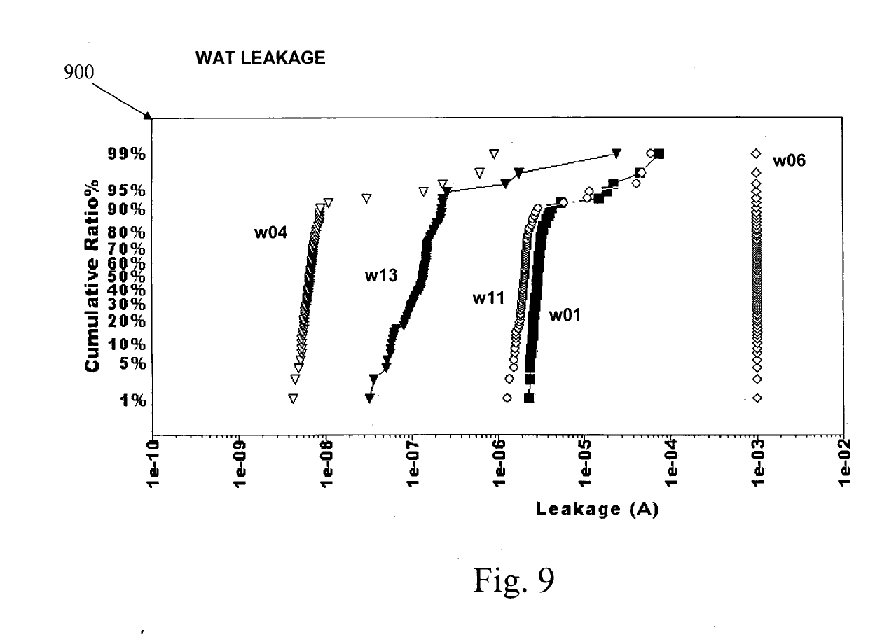

FIGS. 7, 8, and 9 illustrate graphs associated with a plurality of semiconductor wafers (e.g., substrates) at a plurality of steps during the manufacturing process. The graphs illustrate a correlation between inspection methods and illustrate a trend of leakage behavior for the wafers. Specifically, FIG. 7 illustrates a BSI analysis graph 700; FIG. 8 illustrates a BVC analysis graph 800; FIG. 9 illustrates a WAT graph 900. Each graph illustrates a high leakage of wafer number 6 (w06) determined at various points in the manufacturing process.

It is noted that the BSI analysis can identify the high leakage of wafer number 6 at an earlier position in the manufacturing process. The BSI analysis graph 700 represents data gathered after forming a silicide feature (such as the silicide feature described above in step 202 of the method 200). The BVC analysis graph 800 represents data gather after forming a conductive plug (e.g., tungsten plug) contact to a silicide region. For example, the BVC graph 800 may be generated using the method 100, illustrated above with reference to FIG. 1, or portion thereof. It is noted that the BVC graph 800 illustrates a disadvantage of the method 100 and/or BVC analysis in general. Point 802 illustrates that for wafer number 6 with severe leakage, the presented trend is corrected from an originally erroneous voltage contrast comparison result with also no defects. The method 100 does not capture defects due to a saturation of the background gray level. Defect gray level (DGLV) of false defects confirms this effect. The BSI analysis graph 700 does not provide the same issue due, for example, to the use of EPICA methodology in its formation. Finally, WAT graph 900 illustrates a wafer-level measured leakage value. The wafer assessment test (WAT) graph 900 confirms the high leakage level (in Amperes) of wafer number 6. The WAT graph 900 may include leakage levels determined from a test structure. In an embodiment, FIGS. 7, 8, and 9 illustrate devices including a NiSi region and a tungsten plug (Wplug) formed on the NiSi region; however, numerous other embodiments are possible. Thus, FIGS. 7, 8, and 9 illustrate correlation between the e-beam scan post-silicide formation (for example, as described in the method 300) and the final junction leakage as determined by the wafer assessment testing.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of integrated circuit manufacturing, comprising:
forming a silicide region on a semiconductor substrate;
performing an electron beam scan of the semiconductor substrate, wherein the electron beam scan includes a first scan and a second scan, wherein the first scan has a lower landing energy than the second scan; and
forming a conductive plug coupled to the silicide region after performing the electron beam scan.

2. The method of claim 1, wherein the first scan includes a monitor of a physical property of the silicide region.

3. The method of claim 2, wherein the physical property includes an amount of silicide formed in an opening on the semiconductor substrate.

4. The method of claim 1, wherein the first scan includes a monitor of junction leakage.

5. The method of claim 1, wherein the second scan is performed at a landing energy between approximately 500 and 700 eV.

6. The method of claim 1, wherein the first scan is performed at a landing energy of approximately 300 eV.

7. The method of claim 1, wherein the first scan provides a bright silicide image (BSI) and a dark silicide image (DSI).

8. The method of claim 1, wherein the second scan provides a dark silicide image (DSI).

9. The method of claim 8, further comprising:
analyzing the BSI provided by the first scan, wherein the analyzing the BSI includes:
determining a number of BSI counts;
performing a BSI gray level analysis; and
performing a background gray level monitor.

10. The method of claim 1, wherein the conductive plug includes tungsten.

11. The method of claim 1, wherein the silicide region provides a contact to a device feature.

12. The method of claim 11, wherein the device feature includes at least one of a source and a drain of a transistor.

13. A method of integrated circuit manufacturing, comprising:
forming a silicide region on a semiconductor substrate;
performing a first electron beam scan of the semiconductor substrate, wherein the first electron beam scan provides a bright silicide image (BSI) and a first dark silicide image (DSI); and
performing a second electron beam scan of the semiconductor substrate, wherein the second electron beam scan provides a second dark silicide image (DSI).

14. The method of claim 13, further comprising:
forming a conductive plug coupled to the silicide region after performing the first and the second electron beam scan, wherein the forming the conductive plug includes performing a chemical mechanical polish (CMP) process.

15. The method of claim 14, further comprising:
performing a third electron beam scan following the CMP process, wherein the third electron beam scan provides a bright voltage contrast (BVC) image and a dark voltage contrast (DVC) image.

16. The method of claim 13, further comprising:
identifying a defect on the semiconductor substrate, wherein the defect is a dislocation in the semiconductor substrate, and wherein the defect is determined using the BSI.

17. A method of integrated circuit manufacturing, comprising:
performing a first electron beam scan of a semiconductor substrate, wherein the first electron beam scan is at a first landing energy; and
performing a second electron beam scan of the semiconductor substrate, wherein the second electron beam scan is at a second landing energy, and wherein the second landing energy is higher than the first landing energy, and wherein at least one of the first and the second electron beam scan includes scanning the semiconductor substrate to monitor a background gray level value (GLV).

18. The method of claim 17, wherein the second landing energy includes scanning the semiconductor substrate to monitor the background GLV.

19. The method of claim 18, wherein the first electron beam scan provides bright silicide image (BSI).

20. The method of claim 17, wherein the second electron beam scan provides a monitor for a dark silicide image (DSI).
